(19) United States
(12) Patent Application Publication
(10) Pub. No.: US 2013/0092996 A1
(43) Pub. Date: Apr. 18, 2013

(54) NAND FLASH MEMORY DEVICES

(71) Applicants: Chang-Hyun LEE, Suwon-si (KR); Jung-Dal CHOI, Hwaseong-si (KR); Jee-Yeon KANG, Seongnam-si (KR)

(72) Inventors: Chang-Hyun LEE, Suwon-si (KR); Jung-Dal CHOI, Hwaseong-si (KR); Jee-Yeon KANG, Seongnam-si (KR)

(21) Appl. No.: 13/552,877

(22) Filed: Jul. 19, 2012

(30) Foreign Application Priority Data
Oct. 13, 2011 (KR) 10-2011-0104371

(51) Int. Cl. H01L 27/088

(52) U.S. Cl. 257/315; 257/E27.06

(57) ABSTRACT

NAND flash memory device includes a common bit line, a first cell string including a first string selecting transistor having a first gate length, a second string selecting transistor having a second gate length, first cell transistors each having a third gate length and a first ground selecting transistor having a fourth gate length, a second cell string including a third string selecting transistor having the first gate length, a fourth string selecting transistor having the second gate length, second cell transistors each having the third gate length and a second ground selecting transistor having the fourth gate length and a common source line commonly connected to end portions of the first and second ground selecting transistors included in the first and second cell strings. At least one of the first gate length and the second gate length is smaller than the fourth gate length.

### CROSS-REFERENCE TO RELATED APPLICATION

This application claims priority under 35 U.S.C. §119 to Korean Patent Application No. 10-2011-0104371, filed on Oct. 13, 2011 in the Korean Intellectual Property Office, the contents of which are incorporated herein by reference in their entirety.

### BACKGROUND

Example embodiments relate to NAND flash memory devices. More particularly, the example embodiments relate to NAND flash memory devices including a common bit line structure.

As a NAND flash memory device has a storing capacity of a large amount of data among semiconductor memory devices, the NAND flash memory device may be used as a main memory in various electronic devices. In order to increase an integration degree of the NAND flash memory device and to increase the data storing capacity of the device, various researches have been conducted.

### SUMMARY

Some embodiments provide highly integrated NAND flash memory devices.

According to some embodiments, a NAND flash memory device may include a common bit line, a first cell string including a first string selecting transistor having an enhancement mode and a first gate length, a second string selecting transistor having a depletion mode and a second gate length, first cell transistors each having a third gate length, and a first ground selecting transistor having a fourth gate length. The first string selecting transistor, the second string selecting transistor, the first cell transistors and the first ground selecting transistor are serially connected to each other, the common bit line being connected to the first string selecting transistor, and at least one of the first gate length and the second gate length is smaller than the fourth gate length. The NAND flash memory device also may include a second cell string including a third string selecting transistor having a depletion mode and the first gate length, a fourth string selecting transistor having an enhancement mode and the second gate length, second cell transistors each having the third gate length and a second ground selecting transistor having the fourth gate length. The third string selecting transistor, the fourth string selecting transistor, the second cell transistors and the second ground selecting transistor are serially connected to each other, the common bit line being connected to the third string selecting transistor. The NAND flash memory device includes a common source line commonly connected to end portions of the first and second ground selecting transistors of the first and second cell strings.

In some embodiments, the first gate length may be smaller than the second gate length.

In some embodiments, the second gate length may be the same as the fourth gate length or the second gate length may be smaller than the fourth gate length.

In some embodiments, a first gate line provided as a common gate of the first and third string selecting transistors may have a smaller line width than a second gate line provided as a common gate of the second and fourth string selecting transistors.

In some embodiments, the second gate length may be smaller than the first gate length.

In some embodiments, the first gate length may be the same as the fourth gate length or smaller than the fourth gate length.

In some embodiments, a second gate line provided as a common gate of the second and fourth string selecting transistors may have a smaller line width than the first gate line provided as the common gate of the first and third string selecting transistors.

In some embodiments, the first gate length and the second gate length may be the same.

In some embodiments, the second gate line provided as the common gate of the second and fourth string selecting transistors may have the same line width as the first gate line provided as the common gate of the first and third string selecting transistors.

In some embodiments, the third gate length may be the same as at least one of the first and second gate lengths or the third gate length may be smaller than the first and second gate lengths.

In some embodiments, each of the first and second cell transistors may include a tunnel oxide layer, a floating gate electrode, a blocking dielectric layer and a control gate electrode integrated one by one. Each of the first to fourth string selecting transistors may include the tunnel oxide layer, the floating gate electrode, the blocking dielectric layer and the control gate electrode integrated one by one. The floating gate electrode and the control gate electrode of each of the first to fourth string selecting transistors may be directly connected to each other.

In some embodiments, each of the first and second cell transistors and each of the first to fourth string selecting transistors may include the tunnel oxide layer, a charge storing layer, the blocking dielectric layer and the control gate electrode integrated one by one.

In some embodiments, the first gate length and the second gate length may be smaller than the fourth gate length.

In some embodiments, a non-volatile memory device is provided. The non-volatile memory device may include a memory cell array, a bit line, and a common source line. The memory cell array may include a plurality of cell strings and each of the plurality of cell strings may include a plurality of transistors serially connected to each other. The bit line may be connected to one end of a first cell string of the plurality of cell strings. The common source line may be connected to the other end of the first cell string. The first cell string may include a first string selecting transistor, a second string selecting transistor, a first set of cell transistors, and a first ground selecting transistor. The first string selecting transistor may have a first gate length and may be connected to the bit line. The second string selecting transistor may have a second gate length and may be serially connected to the first string selecting transistor. The first set of cell transistors may be serially connected to each other and a first end of the first set of cell transistors may be serially connected to the second string selecting transistor. At least one transistor of the first set of cell transistors may have a third gate length. The first ground selecting transistor may have a fourth gate length and a first end of the first ground selecting transistor may be serially connected to the common source line. A second end of the first ground selecting transistor may be serially connected to a second end of the first set of cell transistors. At least one of the first gate length and the second gate length may be smaller than the fourth gate length.

As described above, two neighboring cell strings may be connected to one common bit line in a direction of a word line in a NAND flash memory device in accordance with exemplary embodiments. String selecting transistors included in the cell string may include a gate structure having a narrower line width than a ground selecting transistor. A highly integrated NAND flash memory device may be provided.

### BRIEF DESCRIPTION OF THE DRAWINGS

Exemplary embodiments will be more clearly understood from the following detailed description taken in conjunction with the accompanying drawings. FIGS. 1 to 11 represent exemplary embodiments as described herein.

FIG. 1 is a circuit diagram of a cell array of a NAND flash memory device in accordance with exemplary embodiments.

FIG. 2 is a cross-sectional view of a NAND flash memory device in accordance with exemplary embodiments.

FIG. 3 illustrates applied voltages to the NAND flash memory device illustrated in FIG. 2 during performing a programming operation according to exemplary embodiments.

FIGS. 4A to 4D are cross-sectional views for explaining a method of manufacturing the NAND flash memory device illustrated in FIG. 2 according to exemplary embodiments.

FIG. 5 is a cross-sectional view of a NAND flash memory device in accordance with exemplary embodiments.

FIG. 6 is a cross-sectional view of a NAND flash memory device in accordance with exemplary embodiments.

FIG. 7 is a cross-sectional view of a NAND flash memory device in accordance with exemplary embodiments.

FIG. 8 is a cross-sectional view of a NAND flash memory device in accordance with exemplary embodiments.

FIG. 9 is a cross-sectional view of a NAND flash memory device in accordance with exemplary embodiments.

FIG. 10 is a schematic diagram of a memory card including a NAND flash memory device in accordance with exemplary embodiments.

FIG. 11 is a block diagram of an electronic system including a NAND flash memory device in accordance with exemplary embodiments.

### DETAILED DESCRIPTION OF THE EMBODIMENTS

Various exemplary embodiments will be described more fully hereinafter with reference to the accompanying drawings, in which some exemplary embodiments are shown. The present disclosure may, however, be embodied in many different forms and should not be construed as limited to the exemplary embodiments set forth herein. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. Unless indicated otherwise, these terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof

Exemplary embodiments are described herein with reference to cross-sectional illustrations that are schematic illustrations of idealized exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but are to include deviations in shapes that result, for example, from manufacturing. The regions illustrated in the figures are schematic in nature and their shapes are not intended to limit the scope of the present disclosure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of this specification and the relevant art and will not be interpreted in an idealized or overly formal sense unless expressly so defined herein.

Hereinafter, exemplary embodiments on NAND flash memory devices in accordance with exemplary embodiments will be explained in detail.

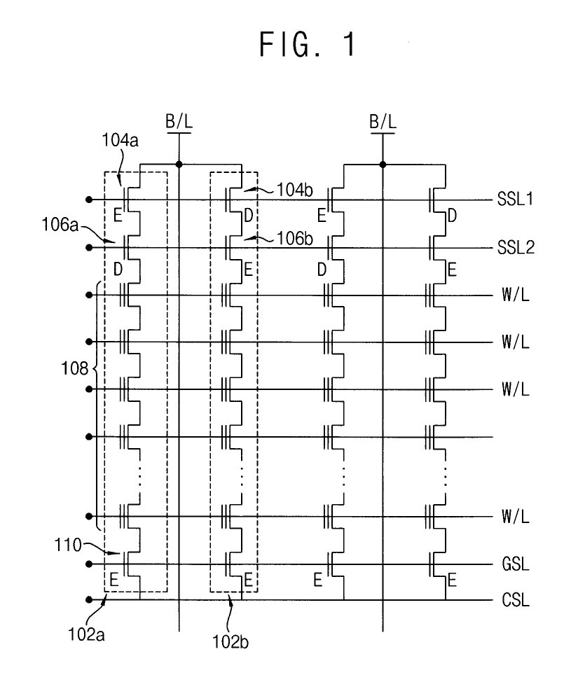

FIG. 1 is a circuit diagram of a cell array of a NAND flash memory device in accordance with exemplary embodiments.

Referring to FIG. 1, a memory cell array may include a first cell string 102a, a second cell string 102b neighboring the first cell string 102a in a direction of a word line, a common bit line B/L commonly connected to end portions of the first and second cell strings 102a and 102b, and a common source line CSL commonly connected to the other end portions of the first and second cell strings 102a and 102b.

The memory cell array may include repeatedly disposed unit cell strings, each cell string immediately adjacent to at least one other cell string, including one common bit line B/L and two cell strings 102a and 102b connected to the common bit line B/L.

The first cell string 102a may include two serially connected string selecting transistors 104a and 106a and the second cell string 102b may include two serially connected string selecting transistors 104b and 106b, respectively. The two serially connected string selecting transistors 104a and 106a may have different threshold voltages and may include different transistor modes within the first cell string 102a. Similarly, the two serially connected string selecting transistors 104b and 106b may have different threshold voltages and may include different transistor modes within the second cell string 102b. Particularly, one of the two string selecting transistors 104a and 106a included in the first cell string 102a may be an enhancement mode transistor (E) and the other of the two string selecting transistors 104a and 106a may be a depletion mode transistor (D). Similarly, one of the two string selecting transistors 104b and 106b included in the second cell string 102b may be an enhancement mode transistor (E) and the other of the two string selecting transistors 104b and 106b may be a depletion mode transistor (D).

The first cell string 102a may include a first string selecting transistor 104a of an enhancement mode, a second string selecting transistor 106a of a depletion mode, cell transistors 108 and a ground selecting transistor 110, serially connected one by one. The second cell string 102b may include a third string selecting transistor 104b of a depletion mode, a fourth string selecting transistor 106b of an enhancement mode, cell transistors 108 and a ground selecting transistor 110, serially connected one by one.

The enhancement mode transistor (E) may be a transistor including a channel region having a different conducting mode from source/drain regions. Particularly, the channel region of the enhancement mode transistor (E) may be doped with p-type impurities and each of the source/drain regions of the enhancement mode transistor (E) may be doped with n-type impurities. The enhancement mode transistor (E) may have a threshold voltage greater than 0V.

The depletion mode transistor (D) may be a transistor including a channel region having the same conducting mode with the source/drain regions. Particularly, the channel region of the depletion mode transistor (D) may be doped with n-type impurities and each of the source/drain regions of the depletion mode transistor (D) may be doped with n-type impurities. The depletion mode transistor (D) may have a threshold voltage smaller than 0V.

Hereinafter, the first and third string selecting transistors 104a and 104b, connected to the common bit line B/L directly in each cell strings may be set as a first group string selecting transistor. The second and fourth string selecting transistors 106a and 106b neighboring the cell transistors may be set as a second group string selecting transistor.

Impurity regions of the ground selecting transistors 110 included in the first and second cell strings 102a and 102b may be connected to the common source line CSL.

Gates of the transistors included in the first and second cell strings 102a and 102b may be connected to each other in the direction of the word line. Each of the gates in the ground selecting transistors 110 may be connected to each other in the direction of the word line. The gates of the first and third string selecting transistors 104a and 104b may be provided as a first gate line SSL1, the gates of the second and fourth string selecting transistors 106a and 106b may be provided as a second gate line SSL2, and the gates of the cell transistors may be provided as word lines W/L.

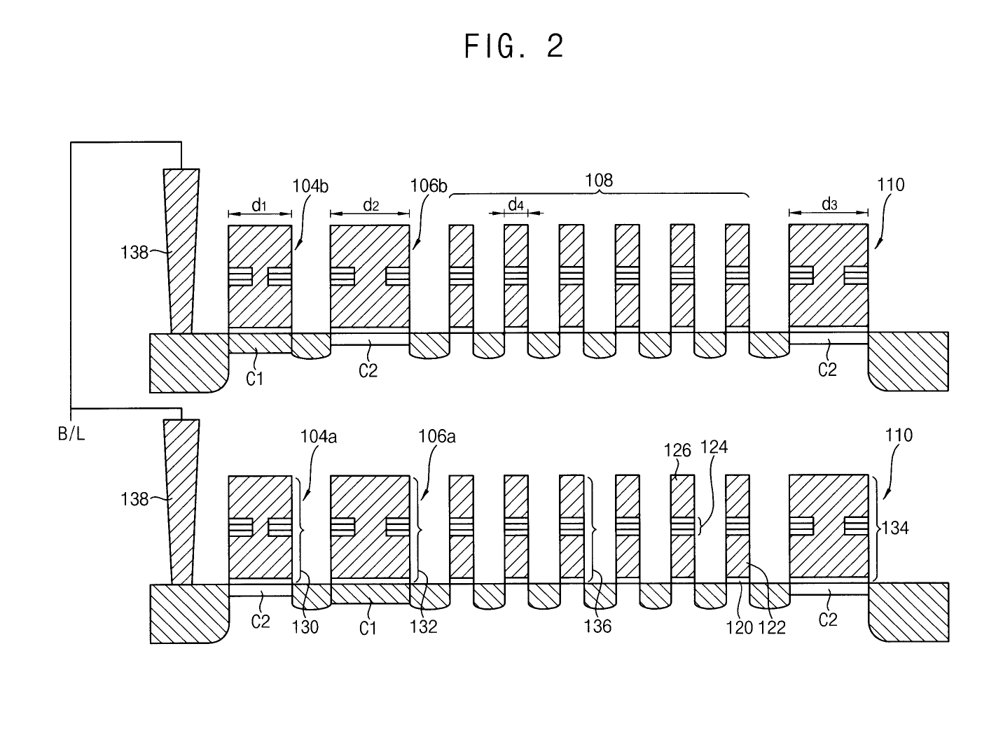

FIG. 2 is a cross-sectional view of the NAND flash memory device in accordance with exemplary embodiments. The lower part of the cross-sectional view illustrates the first cell string and the upper part of the cross-sectional view illustrates the second cell string in FIG. 2.

Referring to FIG. 2, the first group string selecting transistor including the first and third string selecting transistors 104a and 104b may have a first gate length d1. The second group string selecting transistor including the second and fourth string selecting transistors 106a and 106b may have a second gate length d2 greater than the first gate length d1.

The ground selecting transistor 110 may have a third gate length d3, that is the same as the second gate length d2 or greater than the second gate length d2. The cell transistors 108 may have a fourth gate length d4, that is the same as the first gate length d1 or smaller than the first gate length d1.

For example, the first gate length d1 may be smaller than the third gate length d3 by an amount greater than 20% (e.g., between 25%˜35%).

Integrated structure of the transistors included in each cell string will be explained hereinafter.

As illustrated in FIG. 2, the first group string selecting transistor may include a first gate structure 130 including a tunnel oxide layer 120, a floating gate electrode 122, a blocking dielectric layer 124 and a control gate electrode 126 stacked one by one. The blocking dielectric layer 124 may be partially removed in the first gate structure 130 and so, the floating gate electrode 122 and the control gate electrode 126 may be directly connected to each other. The floating gate electrode 122 may include polysilicon. The blocking dielectric layer 124 may have a stacked structure of an oxide material, a nitride material and an oxide material. Alternatively, the blocking dielectric layer 124 may include a metal oxide having a high dielectric constant.

The control gate electrode 126 in the first gate structure 130 may have a line shape. Accordingly, the control gate electrode 126 may be provided as the first gate line SSL1, which may be a common gate of the first group string selecting transistor. The first gate line SSL1 may have a first line width. The first line width may be the same as the word line W/L or greater than the word line W/L of the cell transistors 108.

The second group string selecting transistor may include a second gate structure 132 including the same stacked structure as the first gate structure 130. The floating gate electrode 122 and the control gate electrode 126 may also be directly connected to each other in the second gate structure 132.

The control gate electrode 126 in the second gate structure 132 may have a line shape. Accordingly, the control gate electrode 126 may be provided as the second gate line SSL2, which may be a common gate of the second group string selecting transistor. The second gate line SSL2 may have a second line width greater than the first line width. Accordingly, the second gate length d2 of the second group string selecting transistor may be greater than the first gate length d1 of the first group string selecting transistor. The second gate length d2 of the second group string selecting transistor may be greater than the gate length of the cell transistors d4. Therefore, the generation of a program disturbance of the cell transistors adjacent to the second group string selecting transistor may be restrained.

The ground selecting transistor 110 may include a third gate structure 134 including the same stacked structure as the first gate structure 130. The floating gate electrode 122 and the control gate electrode 126 may be directly connected to each other. The control gate electrode 126 in the third gate structure 134 may have a line shape. Accordingly, the control gate electrode 126 may be provided as the ground selecting line GSL, which may be a common gate of the ground selecting transistors.

The ground selecting line GSL may have a third line width greater than the first line width. The third line width may be the same as the second line width or greater than the second line width. The gate of the ground selecting transistor 110 may have a greater length than those of the cell transistors. As the gate length of the ground selecting transistor 110 increases, the channel length may be increased and the generation of the program disturbance of the cell transistors adjacent to the ground selecting line GSL may be restrained.

While performing the programming operation, a channel boosting may occur in the cell transistors in the cell string not selected. Accordingly, a gate induced drain leakage (GIDL) may be generated by a voltage difference between a gate and a drain of the ground selecting transistor 110 included in the cell string not selected. In this case, undesirable programming operation may be performed for the not selected cell transistors adjacent to the ground selecting transistors 110. In order to restrain the generation of the program disturbance, the ground selecting transistor 110 may be required to have a sufficiently long channel length. The ground selecting line GSL may have a line width, that is the same as the second line width or greater than the second line width.

Each of the cell transistors 108 may include a fourth gate structure 136 including the tunnel oxide layer 120, the floating gate electrode 122, the blocking dielectric layer 124 and the control gate electrode 126 stacked one by one. The control gate electrode 126 may have a line shape and may extend to be provided as a common gate, i.e., a word line W/L. Impurity doped regions may be provided at both sides of the fourth gate structure 136. The fourth gate structure 136 may have a fourth line width, that is the same as the first line width or smaller than the first line width.

As described above, the second and third string selecting transistors 106a and 104b may be the depletion mode transistors (D) and may include a channel region C1 and impurity regions doped with n-type impurities. The first and fourth string selection transistors 104a and 106b may be the enhancement mode transistors (E) and may include source/drain regions doped with n-type impurities and a channel region C2 doped with p-type impurities.

When a programming operation is performed on the NAND flash memory device in accordance with some embodiments, a channel boosting may occur in each cell transistors of the cell string not selected to increase a channel voltage. However, a lower voltage may be applied to the gate of the second group string selecting transistor of the NAND flash memory device of the common bit line structure while performing the programming operation, when compared with each of the gate of the cell transistors.

Accordingly, the channel boosting voltage of the second group string selecting transistor may be lower than the channel boosting voltage of the cell transistor. Thus, the generation of the GIDL may be sufficiently restrained even though the gate length of the first group string selecting transistor may be smaller than the gate length of the second group string selecting transistor. In addition, the gate length of the first group transistor may be decreased to a degree to restrain the GIDL defect.

Hereinafter, a programming operation of the NAND flash memory device illustrated in FIG. 2 may be described in detail.

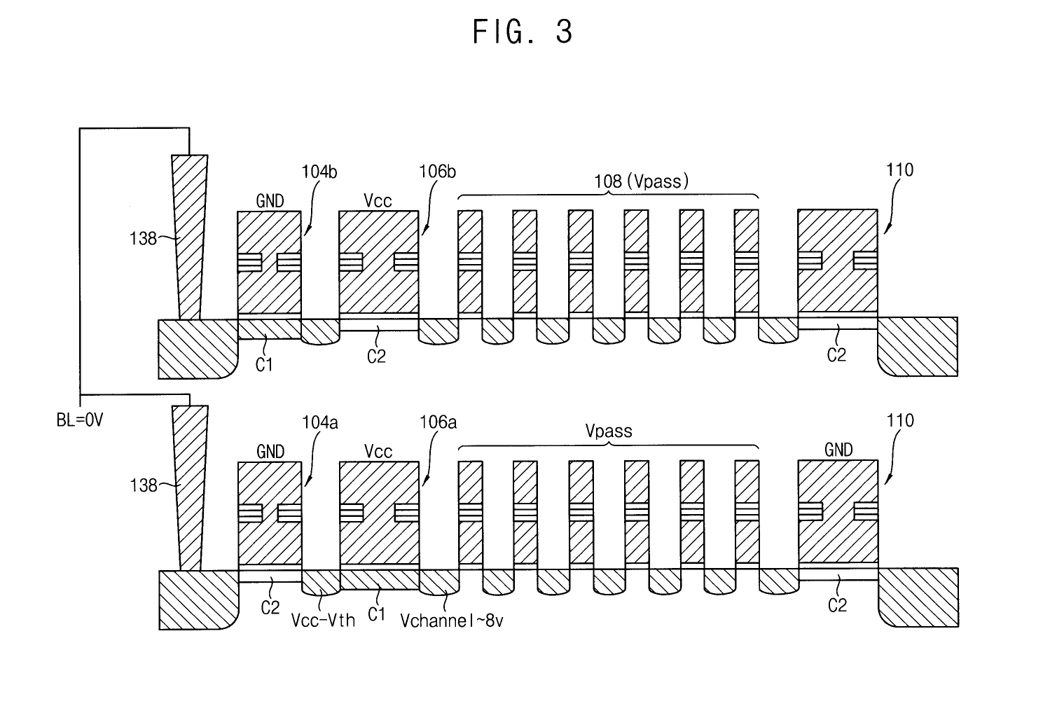

FIG. 3 illustrates voltages applied to the NAND flash memory device while performing a programming operation according to exemplary embodiments.

Referring to FIG. 3, a ground voltage, e.g. 0V may be applied to the common bit line B/L including a cell for performing the programming. Since the programming may be performed with a specific cell of the second cell string, the third and the fourth string selecting transistors 104b and 106b included in the second cell string may be turned on. Since the cells included in the first cell string may not be programmed, at least one of the first and second string selecting transistors 104a and 106a included in the first cell string may be turned off. Accordingly, the ground voltage may be applied to the first gate line SSL1 and a power supply voltage Vcc may be applied to the second gate line SSL2. The power supply voltage Vcc may be a voltage to turn on the fourth string selecting transistor 106b. Particularly, the power supply voltage Vcc may be about 2.3 V and may be lower than a pass voltage Vpass.

Onto the word lines W/L, a program voltage Vpgm or a pass voltage Vpass may be applied. Onto the word lines connected to the selected memory cells, the program voltage Vpgm may be provided and onto the word lines connected to the not selected memory cells, the pass voltage Vpass may be provided. The program voltage Vpgm may be a voltage for programming a corresponding cell and may be high and about 20V. The pass voltage Vpass may be lower than the program voltage but may be high and about 10V.

As described above, since the high voltage of Vpgm or Vpass may be applied to the word lines W/L, a channel may be formed in the cell transistors 108 of the not selected first cell string. In addition, the channel voltage of the cell transistors 108 within the not selected first cell string may be boosted by the program voltage and the pass voltage. Particularly, when the programming voltage is about 20V and the pass voltage is about 10V, the channel voltage may be about 8V.

Since a power supply voltage Vcc lower than the pass voltage Vpass may be applied to the second gate line SSL2 of the second group transistor disposed adjacent to the cell transistors 108, a voltage boosting may be lowered. Accordingly, a channel voltage of the second string selecting transistor 106a may be lower than that of each of the cell transistors 108. Particularly, the channel voltage of the second string selecting transistor 106a may vary depending on the applied power supply voltage Vcc and a threshold voltage of the second string selecting transistor. However, the channel voltage of the second string selecting transistor 106a may be about 70% or less of the channel voltage of the cell transistor.

Onto the first gate line SSL1 of the first group transistors, a ground voltage GND may be applied. However, since the channel voltage of the second string selecting transistor 106a is very low, a drain voltage of the first string selecting transistor 104a may also be lowered. Accordingly, the generation of the GIDL due to a difference between a gate voltage (for example, a ground voltage Vss) and a drain voltage (for example a channel boosting voltage) of the first group string selecting transistors may be restrained.

As described above, the drain voltage of the first group string selecting transistor may be lowered as the second group transistor may be provided. Accordingly, even though the gate length of the first group transistor may be decreased, the generation of the GIDL may be sufficiently restrained.

Hereinafter, a method of manufacturing a NAND flash memory device including a cell array illustrated in FIG. 2 will be explained.

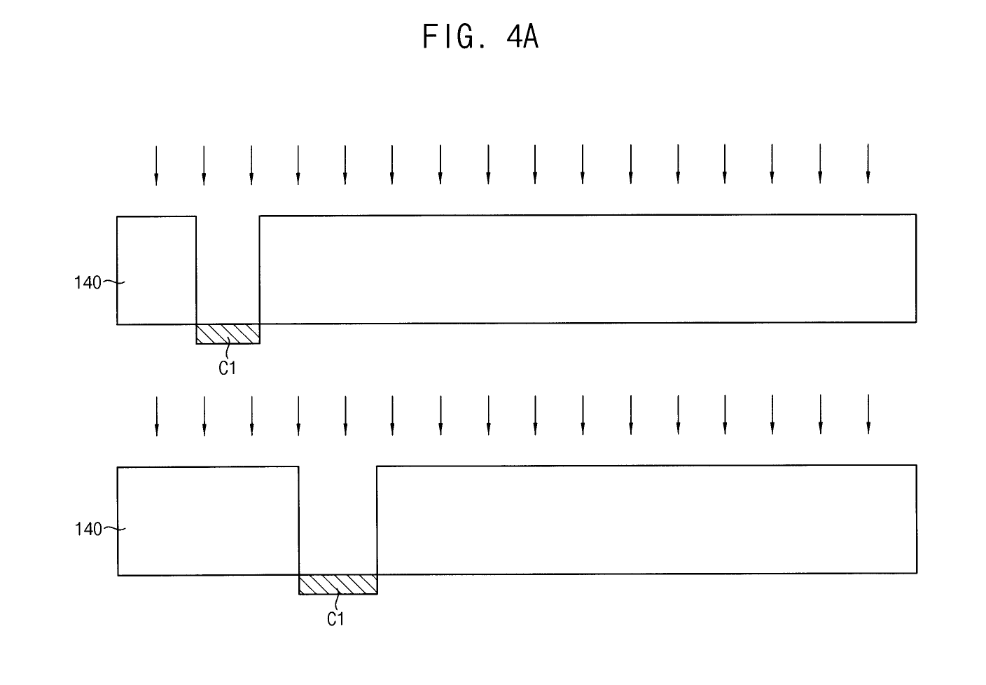

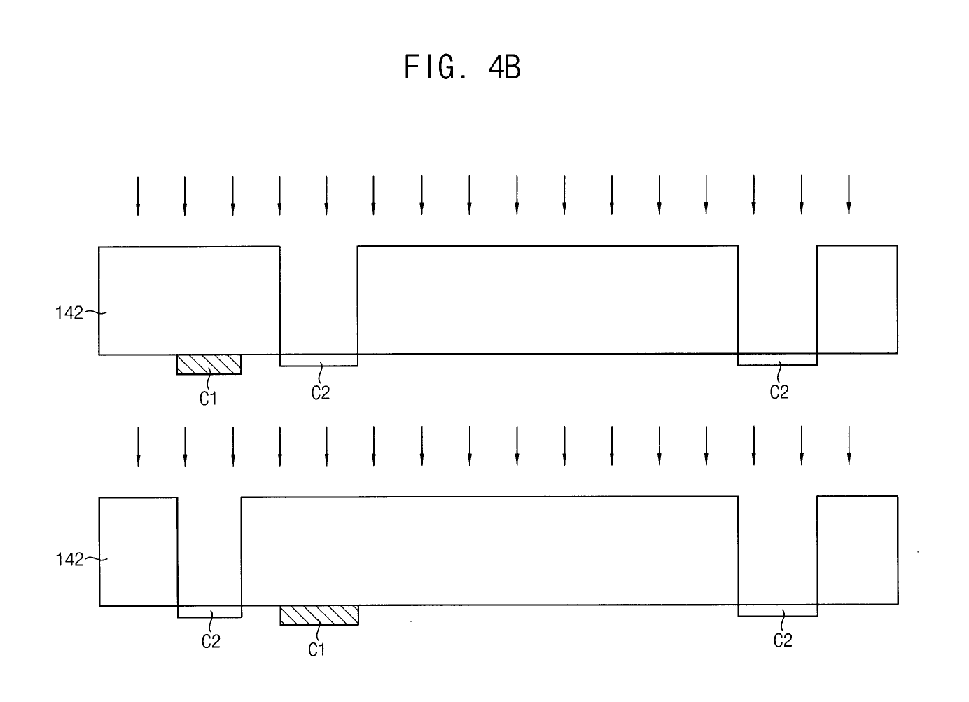

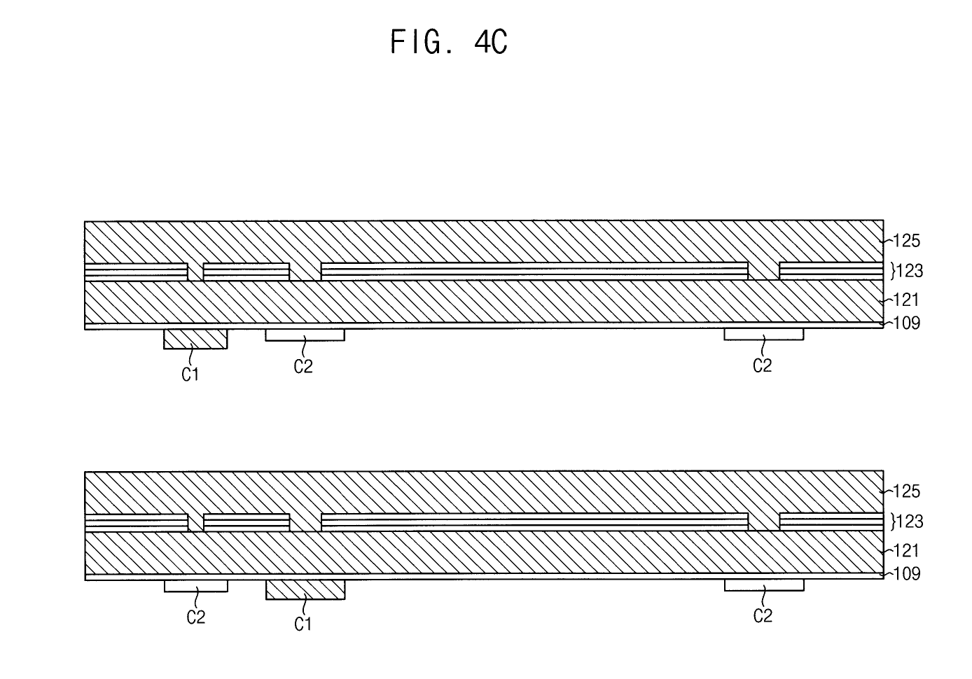

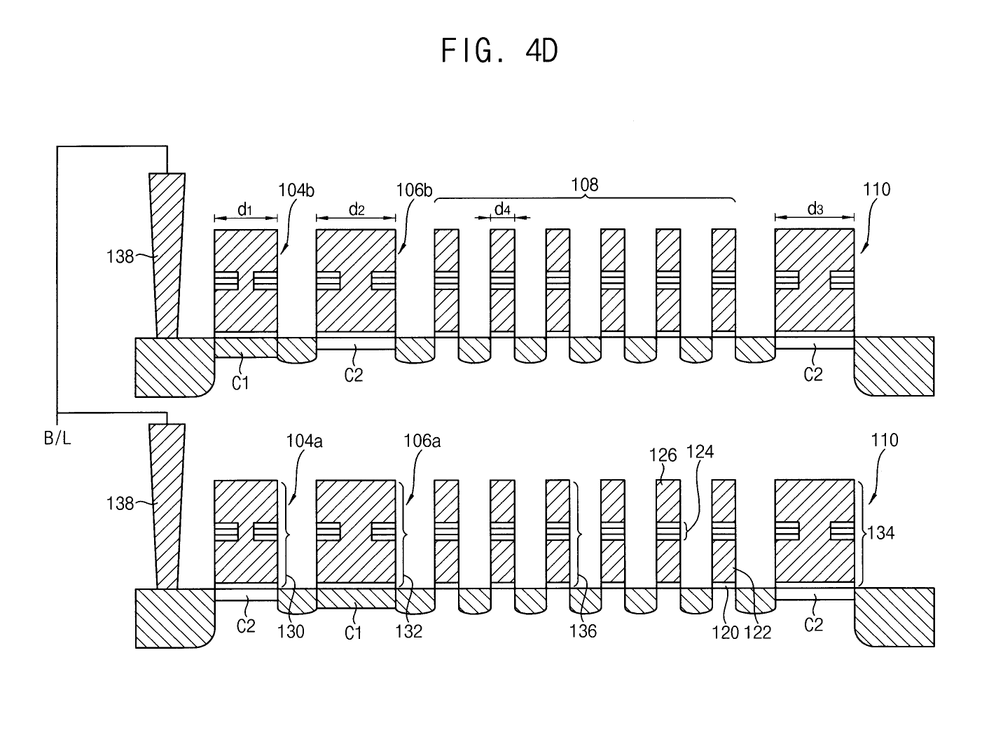

FIGS. 4A to 4D are cross-sectional views for explaining the method of manufacturing the NAND flash memory device illustrated in FIG. 2 according to exemplary embodiments.

Referring to FIG. 4A, a shallow trench device isolation process may be performed with respect to a substrate to form a device isolation layer pattern (not illustrated). The substrate may be lightly doped with p-type impurities. The device isolation layer pattern may have a line shape extending to a first direction. An active region may be formed between the device isolation layer patterns.

In the active region, a first ion implanting mask 140 for selectively exposing a channel region of the second and third string selecting transistors may be formed. Then, n-type impurities may be lightly doped into the exposed regions to form first channel regions C1.

Referring to FIG. 4B, a second ion implanting mask 142 for selectively exposing regions for forming the first and fourth string selecting transistors and regions for forming the ground selecting transistors in the active region. Then, p-type impurities may be doped into the exposed regions to form second channel regions C2.

Through performing the processes, each of the channel regions C1 and C2 of the first to fourth string selecting transistors may be formed. The order of the processes explained referring to FIGS. 4A and 4B may be changed.

Referring to FIG. 4C, a tunnel oxide layer 109, a floating gate electrode layer 121 and a blocking dielectric layer 123 may be formed on the substrate. The floating gate electrode layer 121 may be formed by depositing polysilicon. The blocking dielectric layer 123 may be formed by depositing an oxide material, a nitride material and an oxide material one by one. Alternatively, the blocking dielectric layer 123 may be formed by depositing a metal oxide having a high dielectric constant.

The blocking dielectric layer 123 may be partially removed to expose the floating gate electrode layer 121 to be directly connected a control gate electrode layer 125 for forming the first to fourth string selecting transistors. On the blocking dielectric layer 123 and on the exposed surface of the floating gate electrode layer 121, the control gate electrode layer 125 may be formed.

Referring to FIG. 4D, a mask pattern (not illustrated) may be formed on the control gate electrode layer 125. By utilizing the mask pattern, the control gate electrode layer 125, the blocking dielectric layer 123 and the floating gate electrode layer 121 may be subsequently patterned to form first to fourth gate structures 130, 132, 134 and 136.

While performing the patterning process, the first gate structure 130 for the first group string selecting transistor may be formed to have a first line width. The second gate structure 132 for the second group string selecting transistor may be formed to have a second line width greater than the first line width. The third gate structure 134 for the ground selecting transistor may be formed to have a third line width, that is the same as the second line width or greater than the second line width. The fourth gate structure 136 for the cell transistors may be formed to have a fourth line width, that is the same as the first line width or smaller than the first line width.

For example, n-type impurities may be doped into the active region at both sides of the first to fourth gate structures 130, 132, 134 and 136 and into the active region at both sides of the selecting transistors.

An insulating interlayer (not illustrated) covering the first to fourth gate structures 130, 132, 134 and 136 may be formed. A bit line contact 138 for electrically connecting the impurity region of the first string selecting transistor 104a and the impurity region of the third string selecting transistor 104b may be formed through the insulating interlayer. Then, a bit line B/L making a connection with the bit line contact 138 may be formed. A common source line (not illustrated) making a connection with an impurity region at one side of the ground selecting transistor 110 may be formed.

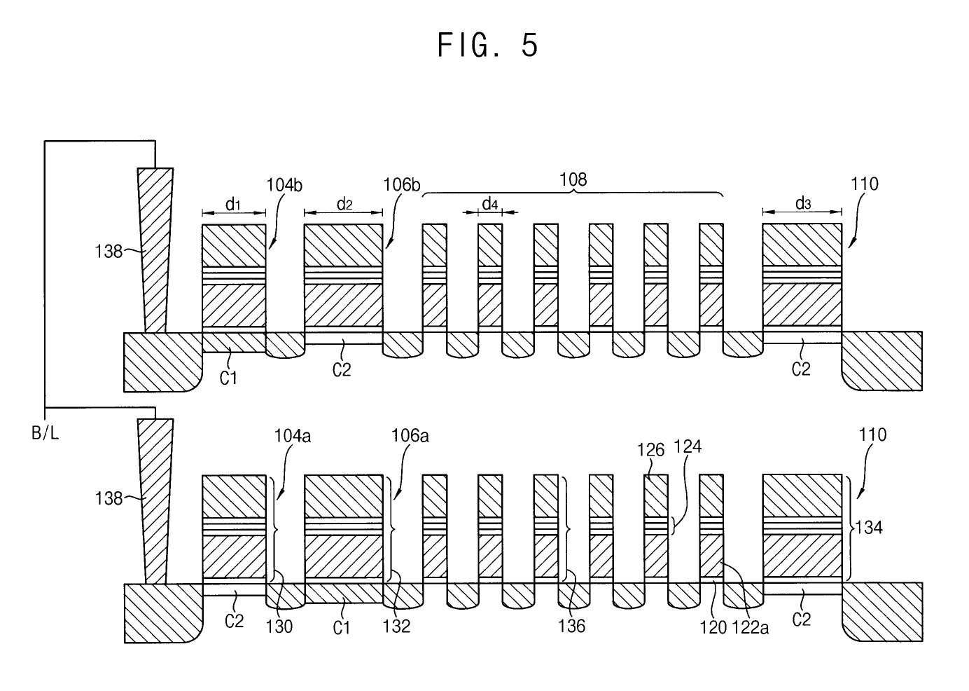

FIG. 5 is a cross-sectional view of a NAND flash memory device in accordance with exemplary embodiments.

The NAND flash memory device illustrated in FIG. 5 may be the same as the NAND flash memory device illustrated in FIG. 2 except for the stacked structure of each of the gate structures.

Referring to FIG. 5, first to fourth gate structures 130, 132, 134 and 136 included in a first group string selecting transistor, a second group string selecting transistor, a ground selecting transistor 110 and cell transistors 108 may have the same stacked structure, respectively. Each of the first to fourth gate structures 130, 132, 134 and 136 may include a tunnel oxide layer 120, a charge storing layer 122a, a blocking dielectric layer 124 and a control gate electrode 126 stacked one by one. The charge storing layer 122a may include, for example, silicon nitride or conductive material (e.g., polysilicon). In one embodiment, each of the blocking dielectric layers 124 of the first group string selecting transistor, a second group string selecting transistor, and a ground selecting transistor 110 may not be removed to partially expose the charge storing layer 122a.

The line widths of the first to fourth gate structures 130, 132, 134 and 136 may be the same as explained referring to FIG. 2. Accordingly, a first gate length d1 of the first group string selecting transistor may be smaller than a second gate length d2 of the second group string selecting transistor. The second gate length d2 of the second group string selecting transistor may be the same as or smaller than a third gate length d3 of the ground selecting transistor 110. A fourth gate length d4 of the cell transistors 108 may be the same as or smaller than the first gate length d1.

The NAND flash memory device illustrated in FIG. 5 may be manufactured by performing the processes explained referring to FIGS. 4A to 4D except for the thin layers stacked for forming each of the gate structures.

Referring to FIGS. 4A to 4D, each of channel regions C1 and C2 of the selecting transistors 104a, 106a, 104b, 106b and 110 may be formed.

Then, a tunnel oxide layer, a charge storing layer, a dielectric layer and a control gate electrode layer may be formed on a substrate. Then, a mask pattern may be formed on the control gate electrode layer.

By utilizing the mask pattern, the control gate electrode layer, the dielectric layer and the charge storing layer may be subsequently patterned to form the first to fourth gate structures 130, 132, 134 and 136. While performing the patterning, the line width of the first to fourth gate structures 130, 132, 134 and 136 may be controlled as illustrated in FIG. 5.

Then, subsequent processes may be performed as illustrated referring to FIG. 4D to complete the NAND flash memory device illustrated in FIG. 5.

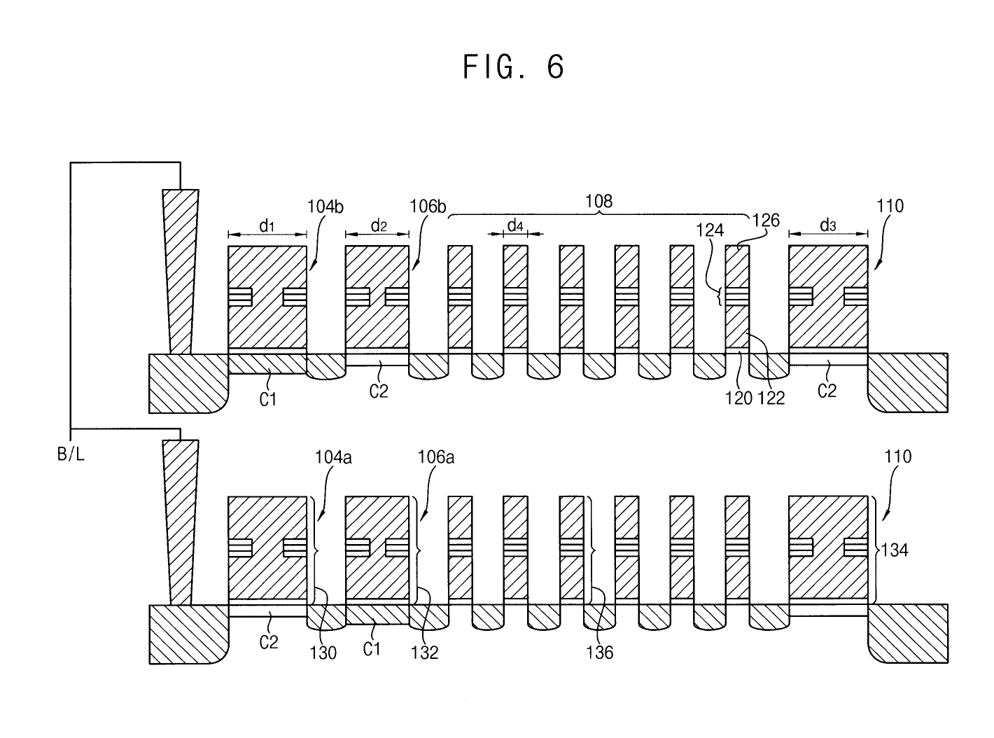

FIG. 6 is a cross-sectional view of a NAND flash memory device in accordance with exemplary embodiments.

The NAND flash memory device explained below may have the same constitution as the circuit diagram illustrated in FIG. 1. In addition, the NAND flash memory device explained below may have the same structure as the NAND flash memory device illustrated in FIG. 2 except for the line widths of the gate structures of the selecting transistors.

Referring to FIG. 6, the first group string selecting transistor including the first and third string selecting transistors 104a and 104b may have a first gate length d1. The second group string selecting transistor including the second and fourth string selecting transistors 106a and 106b may have a second gate length d2 smaller than the first gate length d1.

The ground selecting transistor 110 may have a third gate length d3, that is the same as the first gate length d1 or greater than the first gate length d1. The cell transistors 108 may have a fourth gate length d4, that is the same as the second gate length d2 or smaller than the second gate length d2. For example, the second gate length d2 may be smaller than the third gate length d3 by an amount greater than 20% (e.g., between 25%˜35%).

The first group string selecting transistor, the second group string selecting transistor and the ground selecting transistor 110 may include the first to third gate structures 130, 132 an 134 having the same integrated structures as illustrated in FIG. 2. In addition, the cell transistor 108 may include a fourth gate structure 136 having the same integrated structure as illustrated in FIG. 2. The first to fourth gate structures 130, 132, 134 and 136 may include a tunnel oxide layer 120, a floating gate electrode 122, a blocking dielectric layer 124 and a control gate electrode 126. Further, the first to third gate structures 130, 132 and 134 may include the floating gate electrode 122 and the control gate electrode 126 connected to each other.

As illustrated in FIG. 6, the first gate structure 130 may have a first line width and the second gate structure 132 may have a second line width smaller than the first line width.

Even though the line width of the second gate structure 132 may be decreased, a channel boosting voltage of the second gate structure 132 may be lowered than the channel boosting voltage under the fourth gate structure 136 while performing a programming. By providing the second gate structure 132, defects due to the GIDL may be decreased. Further, by forming the line width of the first gate structure 130 greater than the second gate structure 132, a programming disturbance defect may be restrained.

The third gate structure 134 may have the third line width, that is the same as the second line width or greater than the second line width. The fourth gate structure 136 may have the fourth line width, that is the same as the first line width or smaller than the first line width.

The NAND flash memory device illustrated in FIG. 6 may be manufactured by performing the same processes explained referring to FIG. 4A to 4D, except that an etching mask pattern may be formed so as to form the gate structures having the above-described line widths illustrated in FIG. 6.

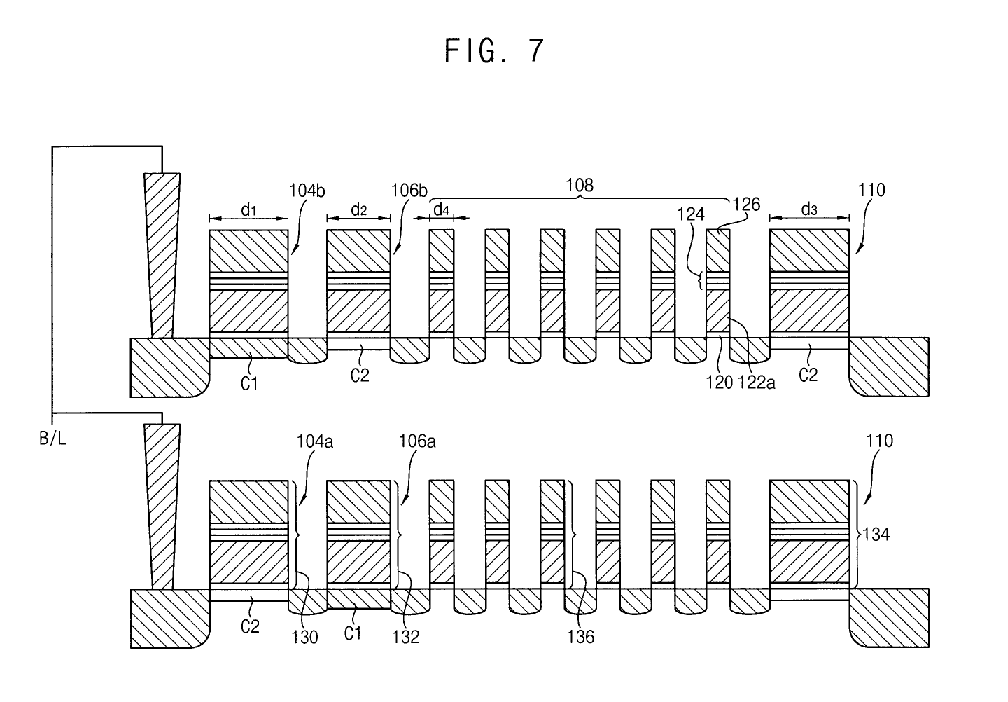

FIG. 7 is a cross-sectional view of a NAND flash memory device in accordance with exemplary embodiments.

Referring to FIG. 7, the NAND flash memory device may be the same as the NAND flash memory device illustrated in FIG. 6 except that charge storing layers included in the first to fourth gate structures 130, 132, 134 and 136 may be used as charge storing layer 122a.

The first to fourth gate structures 130, 132, 134 and 136 may include a tunnel oxide layer 120, a charge storing layer 122a, a blocking dielectric layer 124 and a control gate electrode 126. The charge storing layer 122a may include, for example, silicon nitride or conductive material (e.g., polysilicon).

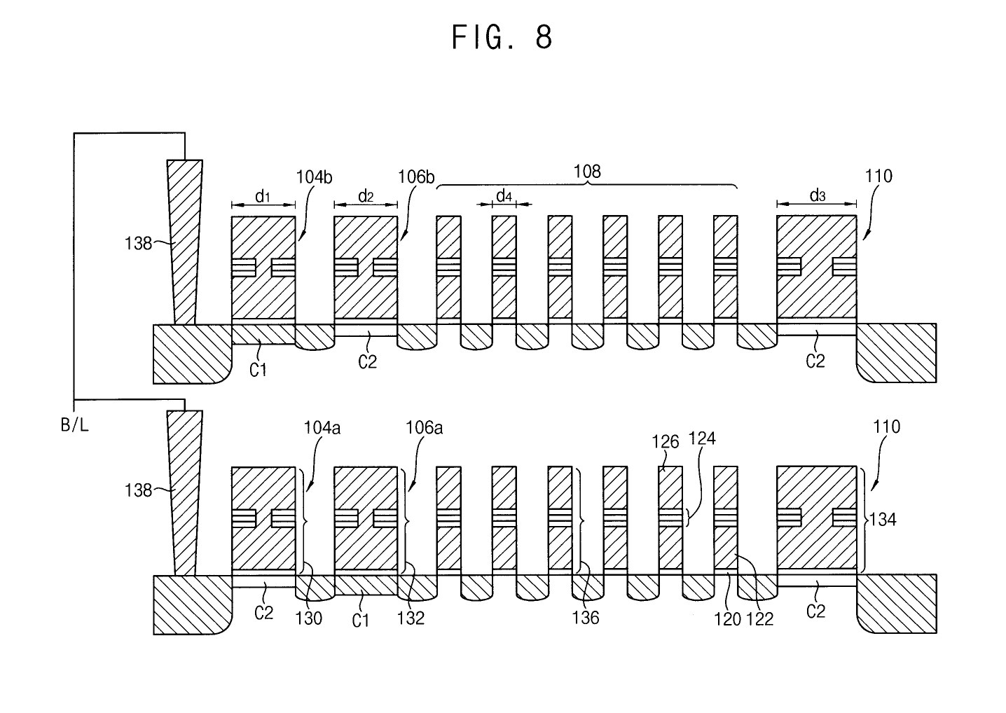

FIG. 8 is a cross-sectional view of a NAND flash memory device in accordance with exemplary embodiments.

The NAND flash memory device may have the same constitution as the circuit diagram illustrated in FIG. 1. The NAND flash memory device may be the same as the NAND flash memory device illustrated in FIG. 2 except for the line width of the gate structure of the selecting transistor.

Referring to FIG. 8, a first group string selecting transistor including first and third string selecting transistors 104a and 104b may have a first gate length d1. A second group string selecting transistor including second and fourth string selecting transistors 106a and 106b may have a second gate length d2 that is the same as the first gate length d1.

A ground selecting transistor 110 may have a third gate length d3 greater than the first gate length d1. Each of cell transistors 108 may have a fourth gate length d4, that is the same as the second gate length d2 or smaller than the second gate length d2. For example, the first gate length d1 and the second gate length d2 may be smaller than the third gate length d3 by an amount greater than 20% (e.g., between 25%˜35%).

Each of the first group string selecting transistor, the second group string selecting transistor, the ground selecting transistor 110 and the cell transistors 108 may include the first to fourth gate structures 130, 132, 134 and 136 having the same stacked structures as illustrated in FIG. 2.

As illustrated in FIG. 8, the first gate structure 130 may have a first line width and the second gate structure 132 may have a second line width, which is the same as the first line width. The third gate structure 134 may have a third line width greater than the first and second line widths.

Even though the first and second line widths are formed smaller than the line width of the third gate structure, since a boosting channel voltage under the second gate structure is low, a programming disturbance defects due to the GIDL may be restrained.

The NAND flash memory device illustrated in FIG. 8 may be manufactured by the same processes explained referring to FIGS. 4A to 4D, except that the first to fourth gate structures being formed while patterning the gate structures to have the line widths illustrated in FIG. 8.

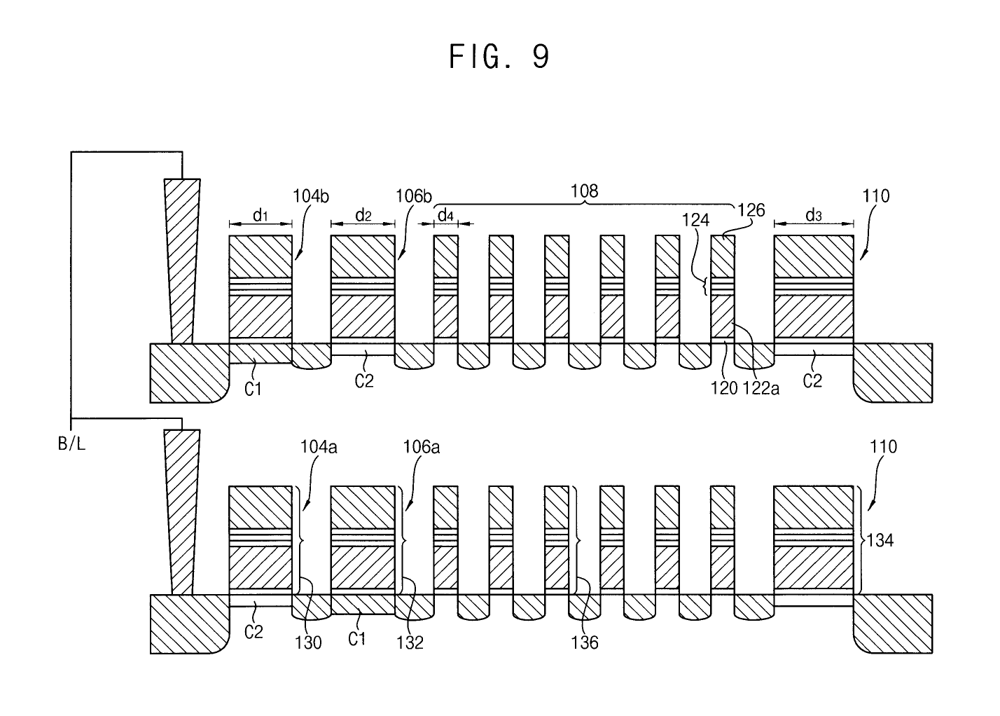

FIG. 9 is a cross-sectional view of a NAND flash memory device in accordance with exemplary embodiments.

The NAND flash memory device illustrated in FIG. 9 may be the same as the NAND flash memory device illustrated in FIG. 8 except that charge storing layers included in the first to fourth gate structures 130, 132, 134 and 136 are used as charge storing layer 122a.

The first to fourth gate structures 130, 132, 134 and 136 may include a tunnel oxide layer 120, a charge storing layer 122a, a blocking dielectric layer 124 and a control gate electrode 126, respectively. The charge storing layer 122a may include, for example, silicon nitride or conductive material (e.g., polysilicon).

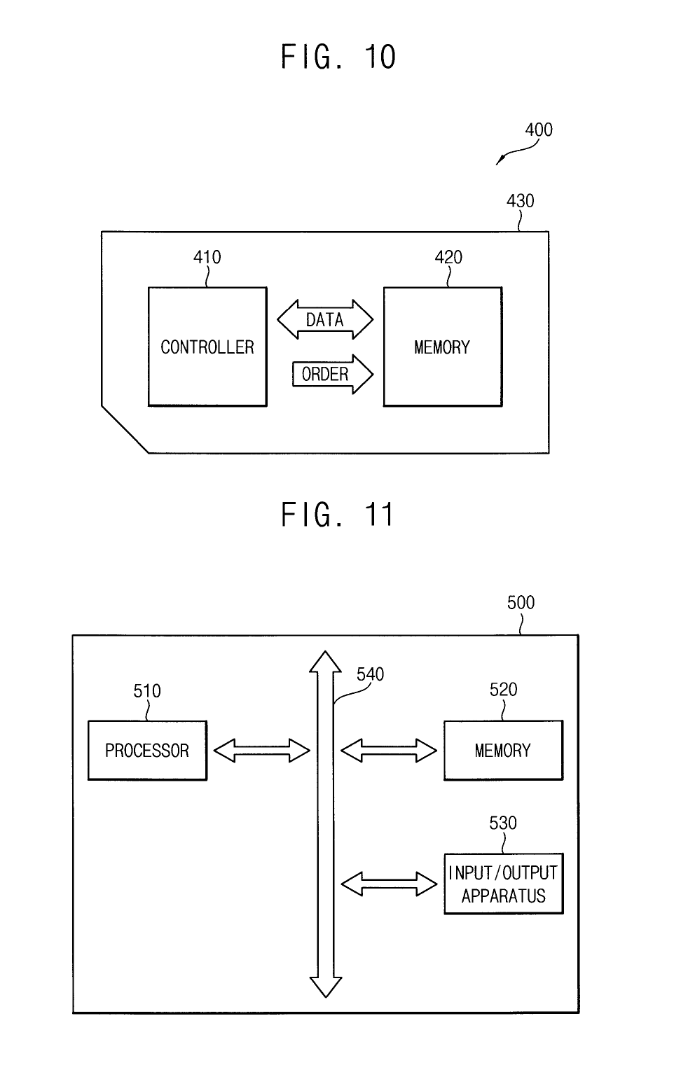

FIG. 10 is a schematic diagram of a memory card including a NAND flash memory device in accordance with exemplary embodiments.

Referring to FIG. 10, a memory card 400 may include a controller 410 and a memory 420 within a housing 430. The controller 410 and the memory 420 may exchange electric signals. Particularly, the memory 420 and the controller 410 may exchange data depending on an order of the controller 410. Accordingly, the memory card 400 may store data in the memory 420 or may output the data from the memory 420.

Particularly, the memory 420 may include a nonvolatile memory device such as the NAND flash memory device in accordance with exemplary embodiments as described above. The memory card 400 may be used as a data storing medium for various portable devices. For example, the memory card 400 may include a multi media card (MMC), a secure digital card (SD), etc.

FIG. 11 is a block diagram of an electronic system including a NAND flash memory device in accordance with exemplary embodiments.

Referring to FIG. 11, an electronic system 500 may include a processor 510, an input/output apparatus 530 and a memory 520. The elements may perform data communication by using a bus 540. The processor 510 may perform programming and may function to control the system 500. The input/output apparatus 530 may be used for inputting or outputting data of the system 500. The system 500 may exchange data with exterior apparatus including a personal computer or a network by using the input/output apparatus 530. The memory 520 may store codes and data for an operation of the processor 510. Particularly, the memory 510 may include a nonvolatile memory device such as the NAND flash memory device in accordance with exemplary embodiments as described above.

As explained above, a highly integrated NAND flash memory device including a common bit line may be provided. The NAND flash memory device may constitute various electronically controlled devices. Particularly, a mobile phone, an MP3 player, navigation, a solid state disk (SSD), household appliances, etc. may be illustrated.

The foregoing is illustrative of exemplary embodiments and is not to be construed as limiting thereof Although a few exemplary embodiments have been described, those skilled in the art will readily appreciate that many modifications are possible in the exemplary embodiments without materially departing from the novel teachings and scopes of the present disclosure. Accordingly, all such modifications are intended to be included within the scope of the present disclosure as defined in the claims. In the claims, means-plus-function clauses are intended to cover the structures described herein as performing the recited function and not only structural equivalents but also equivalent structures. Therefore, it is to be understood that the foregoing is illustrative of various exemplary embodiments and is not to be construed as limited to the specific exemplary embodiments disclosed, and that modifications to the disclosed exemplary embodiments, as well as other exemplary embodiments, are intended to be included within the scope of the appended claims.

What is claimed is:

1. A NAND flash memory device comprising:
a common bit line;
a first cell string including a first string selecting transistor having an enhancement mode and a first gate length, a second string selecting transistor having a depletion mode and a second gate length, first cell transistors each having a third gate length, and a first ground selecting transistor having a fourth gate length, the first string selecting transistor, the second string selecting transistor, the first cell transistors, and the first ground selecting transistor being serially connected to each other, the common bit line being connected to the first string selecting transistor, and at least one of the first gate length and the second gate length being smaller than the fourth gate length;
a second cell string including a third string selecting transistor having a depletion mode and the first gate length, a fourth string selecting transistor having an enhancement mode and the second gate length, second cell transistors each having the third gate length and a second ground selecting transistor having the fourth gate length, the third string selecting transistor, the fourth string selecting transistor, the second cell transistors, and the second ground selecting transistor being serially connected to each other, the common bit line being connected to the third string selecting transistor; and
a common source line commonly connected to end portions of the first and second ground selecting transistors of the first and second cell strings.

2. The NAND flash memory device of claim 1, wherein the first gate length is smaller than the second gate length.

3. The NAND flash memory device of claim 2, wherein the second gate length is the same as the fourth gate length or the second gate length is smaller than the fourth gate length.

4. The NAND flash memory device of claim 1, wherein a first gate line provided as a common gate of the first and third string selecting transistors has a line width smaller than a second gate line provided as a common gate of the second and fourth string selecting transistors.

5. The NAND flash memory device of claim 1, wherein the second gate length is smaller than the first gate length.

6. The NAND flash memory device of claim 5, wherein the first gate length is the same as the fourth gate length or smaller than the fourth gate length.

7. The NAND flash memory device of claim 1, wherein a second gate line provided as a common gate of the second and fourth string selecting transistors has a line width same as or smaller than a first gate line provided as a common gate of the first and third string selecting transistors.

8. The NAND flash memory device of claim 1, wherein the first gate length and the second gate length are the same.

9. The NAND flash memory device of claim 1, wherein the third gate length is the same as at least one of the first and second gate lengths or the third gate length is smaller than the first and second gate lengths.

10. The NAND flash memory device of claim 1, wherein each of the first and second cell transistors includes a tunnel oxide layer, a floating gate electrode, a blocking dielectric layer and a control gate electrode stacked one by one,
wherein each of the first to fourth string selecting transistors includes the tunnel oxide layer, the floating gate electrode, the blocking dielectric layer and the control gate electrode stacked one by one, and
wherein the floating gate electrode and the control gate electrode of each of the first to fourth string selecting transistors are directly connected to each other.

11. The NAND flash memory device of claim 1, wherein each of the first and second cell transistors and each of the first to fourth string selecting transistors include a tunnel oxide layer, a charge storing layer, a blocking dielectric layer and a control gate electrode stacked one by one.

12. The NAND flash memory device of claim 1, wherein at least one of the first gate length and the second gate length is at least 20% smaller than the fourth gate length.

13. The NAND flash memory device of claim 1, wherein at least one of the first gate length and the second gate length is 25%˜35% smaller than the fourth gate length.

14. A non-volatile memory device comprising:
a memory cell array including a plurality of cell strings, each of the plurality of cell strings including a plurality of transistors serially connected to each other;
a bit line being connected to one end of a first cell string of the plurality of cell strings; and
a common source line being connected to the other end of the first cell string,
wherein the first cell string comprises:
a first string selecting transistor having a first gate length and being connected to the bit line;
a second string selecting transistor having a second gate length and being serially connected to the first string selecting transistor;
a first set of cell transistors being serially connected to each other, a first end of the first set of cell transistors being serially connected to the second string selecting transistor, at least one transistor of the first set of cell transistors having a third gate length; and
a first ground selecting transistor having a fourth gate length, a first end of the first ground selecting transistor being serially connected to the common source line and a second end of the first ground selecting transistor being serially connected to a second end of the first set of cell transistors,
wherein at least one of the first gate length and the second gate length is smaller than the fourth gate length.

15. The non-volatile memory device of claim 14, wherein one of the first string selecting transistor and the second string selecting transistor is an enhancement mode transistor and the other of the first string selecting transistor and the second string selecting transistor is a depletion mode transistor.

16. The non-volatile memory device of claim 14, wherein at least one of the first gate length and the second gate length is at least 20% smaller than the fourth gate length.

17. The non-volatile memory device of claim 14, wherein at least one of the first gate length and the second gate length is 25%˜35% smaller than the fourth gate length.

18. The non-volatile memory device of claim 14, wherein the first gate length is the same as the second gate length or is smaller than the second gate length.

19. The non-volatile memory device of claim 14, wherein the second gate length is smaller than the first gate length.

20. The non-volatile memory device of claim 14, wherein each of the first and second cell transistors and each of the first to fourth string selecting transistors include a tunnel oxide layer, a charge storing layer, a blocking dielectric layer and a control gate electrode stacked one by one.
